(19) United States
(12) Patent Application Publication
(10) Pub. No.: US 2012/0119727 A1
(43) Pub. Date: May 17, 2012

(54) SENSOR WITH HIGH FREQUENCY AC MAGNETIC FIELD

(75) Inventors: Menno Willem Jose Prins, Rosmalen (NL); Leonardus Josephus Ijzendoorn, Eindhoven (NL); Xander Jozef Antoine Janssen, Neerpelt (BE); Mykhaylo Ovsyanko, Eindhoven (NL)

(73) Assignee: KONINKLIJKE PHILIPS ELECTRONICS N.V., EINDHOVEN (NL)

(21) Appl. No.: 12/678,502

(22) PCT Filed: Sep. 16, 2008
(86) PCT No.: PCT/IB08/53746

§ 371 Date: Jan. 31, 2012

(30) Foreign Application Priority Data
Sep. 21, 2007 (EP) 07116923.9

(51) Int. Cl. G01N 27/74; G01R 33/12

(52) U.S. Cl. 324/204; 324/228

(57) ABSTRACT

A sensor device for detecting one or more magnetic particles (102) in a sample fluid is described. The sensor device (100) uses at least one rotating magnetic field generator (108) for applying a rotating magnetic field to the sample and more particularly the one or more magnetic particles (102) incorporated therein. The sensor device also comprises a controller for controlling the magnetic field generator such that the rotating frequency of the applied magnetic field is substantially larger than the critical slipping frequency for the magnetic particle. The effect of the induced rotation is sensed using a sensor element (112). Presence, amount and binding properties of the magnetic particles (102) may be derived from the measured effect. Alternatively or additionally the viscosity of the sample fluid may be determined.

The present invention relates to the field of detecting biological, chemical or bio-chemical particles in a sample. More particularly, the present invention relates to a device and method for detecting at least one magnetic particle, optionally coupled to a target, in a sample fluid.

Magnetic microspheres and nanoparticles have numerous practical uses, ranging from medical to magnetic recording applications. While there is a variety of existing and developing applications, most utilize ensemble properties of the particles. Alternatively, monitoring the rotational behavior of single magnetic particles or a chain of several particles, through standard microscopy techniques, for example, has lead to a new range of potential applications. It is known that magnetic particles can rotate in a rotating magnetic field. Said rotation follows the frequency of the rotating magnetic field up to a certain frequency, the so-called critical slipping rate. At the critical slipping frequency the physical rotation of the magnetic particles stops following the applied magnetic rotation field and the rotation frequency of the magnetic particles drops quickly when the rotation frequency of the magnetic field is further increased. This behaviour is called the nonlinear rotation of a magnetic particle aligning with an external rotating magnetic field in a viscous fluid. For lower external rotation rates, the phase of the rotation of the particle remains locked to that of the external field. Nonlinear rotation occurs at sufficiently high external rotation rates when the magnetic particle cannot overcome the viscous drag, i.e. it cannot keep up with the external field's rotation rate. The phase between the external field and the particle's moment “slips,” and the rotation becomes asynchronous with the external field. The transition from synchronous to asynchronous rotation occurs at the critical slipping rate which depends on physical properties like the viscosity of the environment and the volume, shape, and magnetic moment of the particle.

The influence of a rotating magnetic field on magnetic particles in a sample fluid has been used in the development of sensor devices and methods before. International patent application WO 2005/111596 describes a surface-binding biosensor using rotation magnetic particle labels for enhanced detection specificity.

In a magnetic-particle biosensor, the particles may undergo several processes, e.g. particles approach the sensor surface, bind to the sensor surface, unbind from the sensor surface, etc. These processes generate various orientations and mobilities of the particles. In a rotating-field biosensor, it is important that the torque on the particles is accurately controlled. Therefore, the applied torque should be independent of the orientation and the mobility of the particles.

Another problem in a magnetic biosensor is that magnetic dipole-dipole interactions can occur between the particles. For example, particles can influence each other's trajectory and particle magnetization, and chains of particles can be formed. These processes can complicate the sensor behavior and reduce the predictability and robustness of the sensor signal. Therefore, it is important to be able to reduce magnetic dipole-dipole interactions interfering with the sensor signal.

Also a problem when applying a torque to the magnetic particles in the lower of known frequency range, is the steep rise of the rotation frequency of the magnetic particle up to the critical slipping frequency, and steep decline of the rotation frequency of the magnetic particle when going over the critical slipping frequency. Said steep rise and steep decline of the rotation in a narrow range around the critical slipping frequency, together with the critical slipping frequency being dependent on the nature and size the magnetic particles, strongly limits the reliability of existing assays based on applying a torque to the magnetic particle.

It is an object of the present invention to provide good sensor devices and methods for detecting biological, chemical and/or biochemical analytes in a sample using magnetic or magnetizable objects and applying a torque to the magnetic or magnetizable objects. It is an advantage of embodiments according to the present invention that highly reliable and sensitive detection of analytes can be obtained, e.g. for weakly bound particles, or for particles in bulk. It is another advantage of embodiments according to the present invention that an alternative range of frequencies at which magnetic sensor devices can be operated is provided. The latter advantage allows a higher degree of freedom or flexibility in the set-up of such devices or method, such as in the choice of sensing method or sensor element used in that same method or device. It is an advantage of embodiments according to the present invention that the methods and systems can also be used in agglutination assays.

The above objective is accomplished by a method and device according to the present invention.

In a first aspect, the invention relates to a sensor device for detection of at least one magnetic particle in a sample fluid. The sensor device comprises a rotating magnetic field generating means for applying a rotating magnetic field to the sample fluid containing at least one magnetic particle, a controller for operating the rotating magnetic field generating means so as to apply a rotating magnetic field at a frequency substantially higher than the critical slipping frequency of the magnetic particle, and a sensor element for detecting and/or measuring an effect of the rotating magnetic field on the at least one magnetic particle. It is an advantage of embodiments according to the present invention that dipole-dipole interactions between magnetic particles can be reduced or minimized, resulting in an improved sensitivity and/or an improved reproducibility of the sensor device. It is an advantage of embodiments according to the present invention that a high signal to noise ratio can be obtained. It is an advantage of embodiments of the present invention that torque can be applied to the particles independent of their orientation and/or independent of their mobility.

The sensor element may be adapted for distinguishing a specific binding from a less specific binding between the at least one magnetic particle and a surface of another entity. The controller may be adapted for operating the rotating magnetic field generating means so as to apply a rotating magnetic field with a frequency of at least a factor 10 higher than the critical slipping frequency of the magnetic particle. The controller may be adapted for operating the rotating magnetic field generating means so as to apply a rotating magnetic field which ramps from a frequency lower to a frequency higher than the critical slipping frequency of the magnetic particle or vice versa.

The sensor element may be adapted for detecting and/or measuring a parameter related to rotational or motional behavior of the magnetic particle(s) under influence of said rotating magnetic field. A sensor element may be adapted for measuring a dipole field of the at least one magnetic particle as it rotates.

The rotating magnetic field generating means may comprise an alternating current magnetic field generating means.

The magnetic field generating means may comprise a two-dimensional wire structure. It is an advantage of embodiments according to the present invention that the magnetic field generating means can be easily integrated in the sensor device. It is also an advantage of embodiments according to the present invention that the magnetic field generating means may be on-chip.

The sensor element may be any of a magnetic sensor element, an optical sensor element, an electrical sensor element or an acoustic sensor element, or a combination thereof. The sensor element may be a magnetic sensor element such as for example an AMR, a GMR or a TMR sensor element or a Hall sensor element.

The sensor device furthermore may comprise an additional magnetic field generating means for applying a translational force to the magnetic particles. Applying a translational magnetic force may for example be used for applying a washing step or a concentration and/or separation step. The translational magnetic field may be an inhomogeneous field. The translational field may for example be oriented substantially parallel to the surface of the sensor device or for example be oriented substantially perpendicular to the surface of the sensor device. The actuation induced by the translational field may differ according to the magnetic particle (i.e. material, size or shape) and other factors, e.g. clustering of individual magnetic particles. Differing actuation may result in separation or isolation of particular magnetic particles present in the fluid sample for analysis.

It is an advantage of embodiments according to the present invention that the sensor devices can be used for agglutination assays.

The applied rotating magnetic field may be adapted for inducing an effect on a paramagnetic particle, or, alternatively, adapted for inducing an effect on a superparamagnetic particle.

The sensor device may further comprise a processor for deriving a property of the sample fluid based on the measured effect. The property may be the viscosity of the sample fluid.

The sensor device may also comprise a reaction chamber with walls for holding the sample fluid during detecting and/or measuring of the effect. The magnetic particle may be directly or indirectly bound to a wall of the reaction chamber and the processor may be adapted for deriving from said measured effect a property of the bound magnetic particle.

The processor may be adapted for deriving a property of the binding of the at least one magnetic particle, e.g. thus allowing to distinguish a specific binding from a less specific binding between the at least one magnetic particle and a surface of another entity. Alternatively, the sensor device may comprise a reaction chamber for holding the sample fluid having walls that are not and/or non-specifically functionalised with respect to a target in the sample. It is an advantage of embodiments according to the present invention that the magnetic particle does not need to be bound directly or indirectly to a sensor surface. The latter avoids the need for functionalising of the sensor surface.

In a second aspect, the present invention provides a method for characterising a fluid sample. The method comprises obtaining a fluid sample comprising at least one magnetic particle adapted for binding to at least one target, applying a rotating magnetic field at a frequency substantially higher than the critical slipping frequency of the magnetic particle, measuring an effect of the rotational magnetic field on the at least one magnetic particle in said fluid sample, and deriving therefrom a presence and/or amount of said at least one target in the fluid sample.

The rotating magnetic field may be applied with a frequency of at least a factor 10 higher than the critical slipping frequency of the magnetic particle. The rotating magnetic field may be applied from a frequency lower than to a frequency higher than the critical slipping frequency of the magnetic particle.

The method may be applied to magnetic particle(s) which are free from binding to any surface. In other words, the effect may be measured on the magnetic particle(s) while unattached to a surface of the reaction chamber.

The magnetic particle(s) may be attached to a surface of the reaction chamber, e.g. a sensor surface. The attachment to the surface of the magnetic particle(s) may be direct of indirect. The method may further comprise the step of deriving a property of the binding property(ies) of the magnetic particle to the sensor surface from a motional freedom of the bound magnetic particle.

The present invention also relates to a controller for use in a sensor device that is adapted for operating a rotating magnetic field generating means in the sensor device, so as to apply a rotating magnetic field to a magnetic particle in a sample fluid. The frequency of the rotating magnetic field generating means is controlled to be substantially higher than the critical slipping frequency of the magnetic particle in the sample fluid. Alternatively or additionally, the frequency of the rotating magnetic field generating means is controlled to ramp from a frequency lower than to a frequency higher than the critical slipping frequency of the magnetic particle in the sample fluid.

The invention further provides a computer program product that is adapted for, when executed on a computer, performing the method of characterizing a fluid sample according to aspects and/or embodiments of the present invention. The computer program product may be transmitted over a local or wide area telecommunications network. The invention also provides a machine readable data storage device storing the computer program product.

In one aspect, the present invention also provides a biochip comprising at least one sensor device according to embodiments of the present invention. The present invention also provides the use of the sensor device and/or biochip according to embodiments of the invention in biological or chemical sample analysis.

Particular and preferred aspects of the invention are set out in the accompanying independent and dependent claims. Features from the dependent claims may be combined with features of the independent claims and with features of other dependent claims as appropriate and not merely as explicitly set out in the claims.

The above and other characteristics, features and advantages of the present invention will become apparent from the following detailed description, taken in conjunction with the accompanying drawings, which illustrate, by way of example, the principles of the invention. This description is given for the sake of example only, without limiting the scope of the invention. The reference figures quoted below refer to the attached drawings.

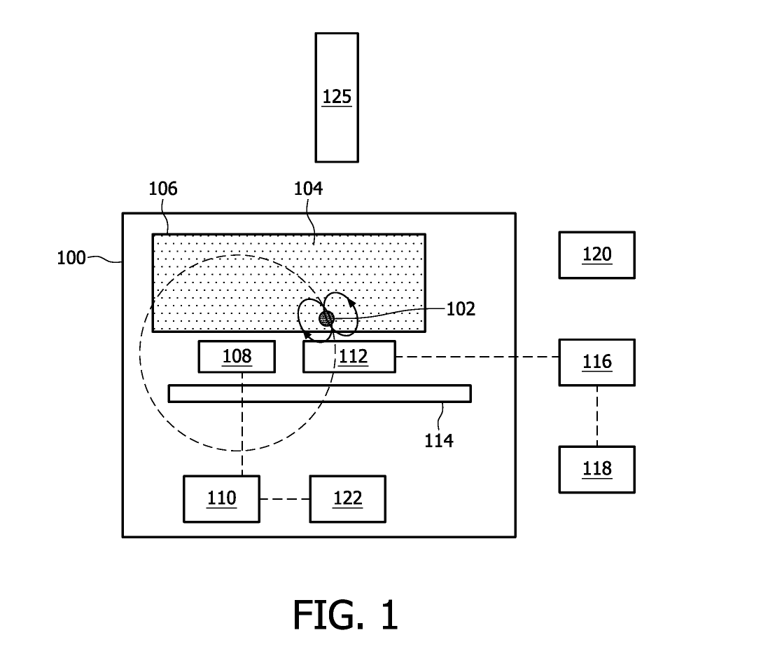

FIG. 1 illustrates an exemplary sensor device according to an embodiment of the present invention.

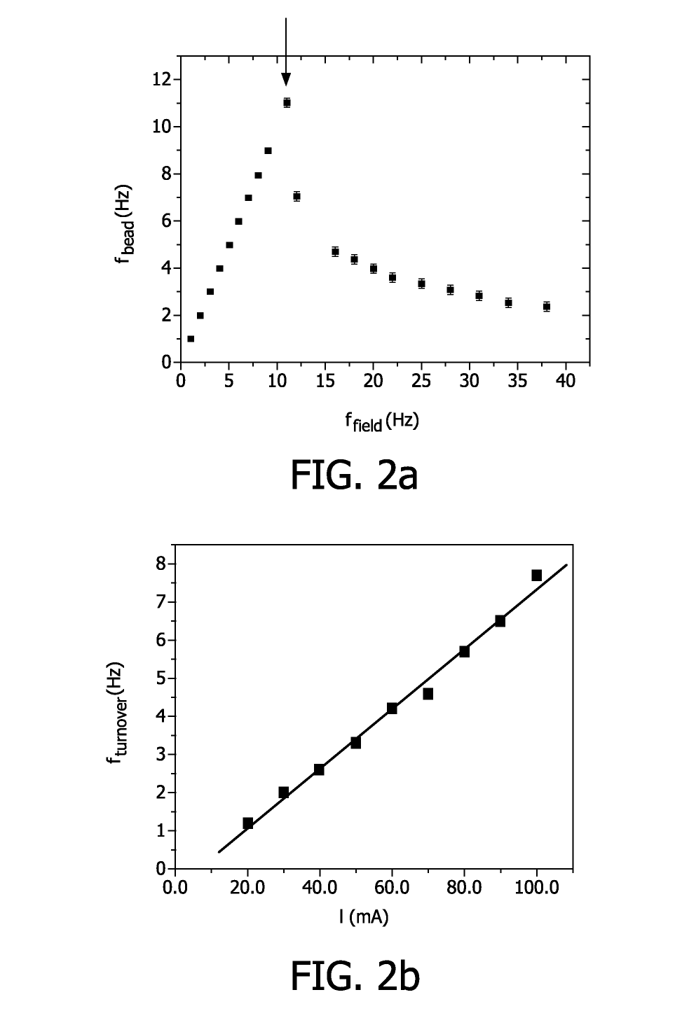

FIG. 2A illustrates the optically measured rotation frequency of the particle as function of applied angular frequency of the rotating magnetic field in a limited frequency range, as known from prior art.

FIG. 2B illustrates the critical slipping frequency as function of applied current in current wires for applying a rotating magnetic field as generated in FIG. 2A.

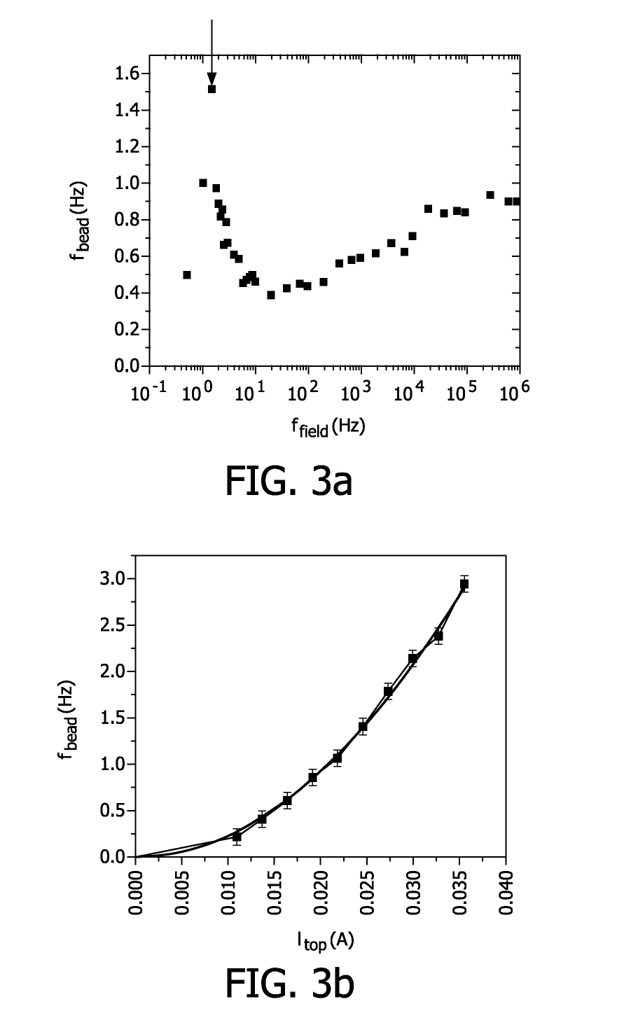

FIG. 3A illustrates the optically measured rotation frequency of a single magnetic bead as function of the applied in a wide angular frequency range, as can be used in embodiments according to the present invention.

FIG. 3B illustrates the critical slipping frequency as function of the applied current in current wires for applying a rotating magnetic field as generated in FIG. 3A, as can be used in embodiments according to the present invention.

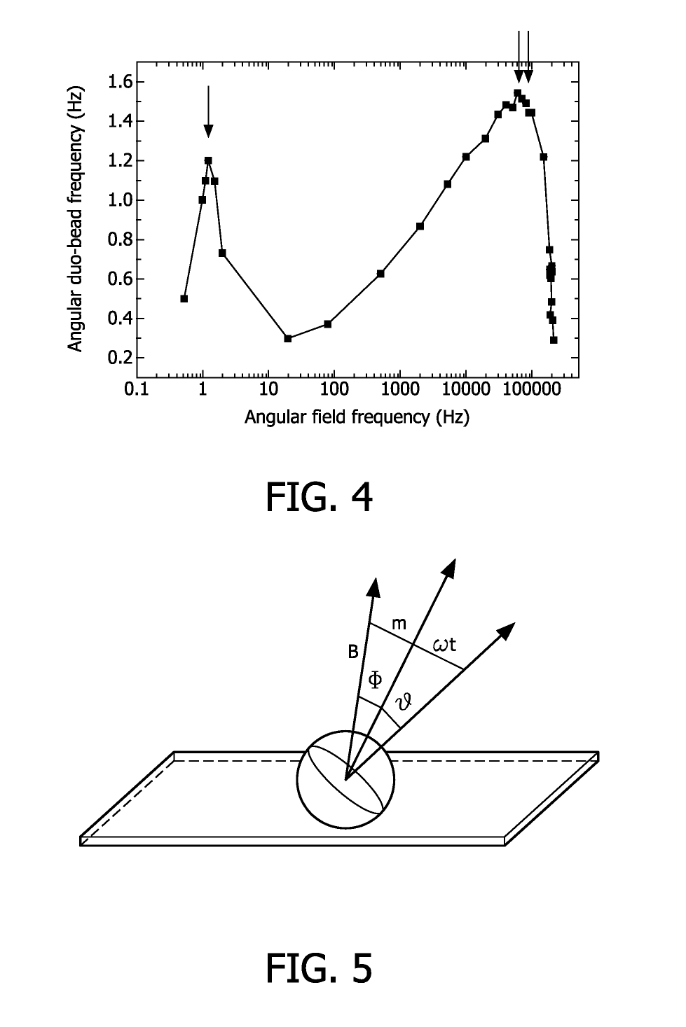

FIG. 4 illustrates the optically measured rotation frequency of a single magnetic bead as function of the applied field in a wide angular frequency range, as can be used in embodiments according to the present invention.

FIG. 5 is a schematic representation of a rotationally driven magnetic particle.

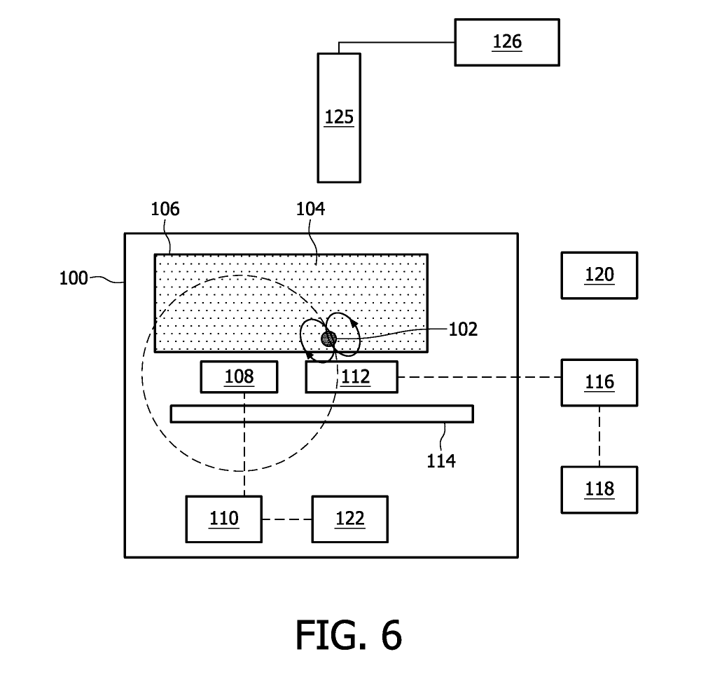

FIG. 6 illustrates another exemplary sensor device according to an embodiment of the present invention.

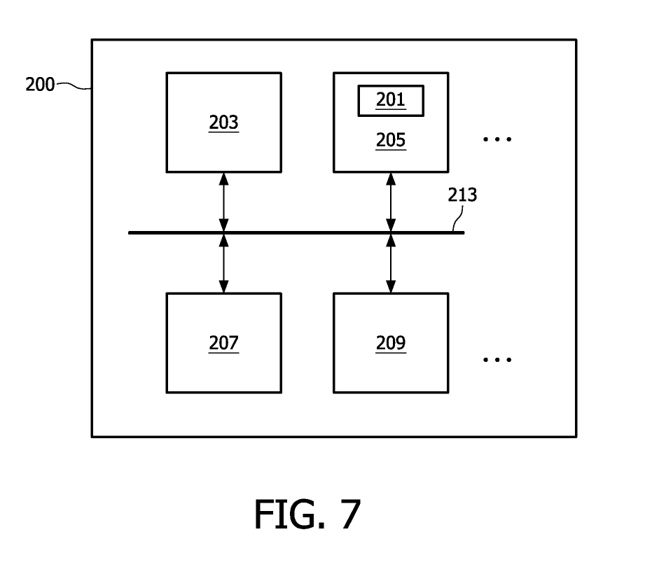

FIG. 7 illustrates a computing system as can be used in embodiments according to the present invention. In the different figures, the same reference signs refer to the same or analogous elements.

The present invention will be described with respect to particular embodiments and with reference to certain drawings but the invention is not limited thereto but only by the claims. Any reference signs in the claims shall not be construed as limiting the scope. The drawings described are only schematic and are non-limiting. In the drawings, the size of some of the elements may be exaggerated and not drawn on scale for illustrative purposes.

Where the term “comprising” is used in the present description and claims, it does not exclude other elements or steps. Where an indefinite or definite article is used when referring to a singular noun e.g. “a” or “an”, “the”, this includes a plural of that noun unless something else is specifically stated.

Furthermore, the terms first, second, third and the like in the description and in the claims, are used for distinguishing between similar elements and not necessarily for describing a sequence, either temporally, spatially, in ranking or in any other manner. It is to be understood that the terms so used are interchangeable under appropriate circumstances and that the embodiments of the invention described herein are capable of operation in other sequences than described or illustrated herein.

The elements and components of an embodiment of the invention may be physically, functionally and logically implemented in any suitable way. Indeed, the functionality may be implemented in a single unit, in a plurality of units or as part of other functional units. As such, the invention may be implemented in a single unit, or may be physically and functionally distributed between different units and processors.

Moreover, the term bottom and the like in the description and the claims are used for descriptive purposes and not necessarily for describing relative positions. It is to be understood that the terms so used are interchangeable under appropriate circumstances and that the embodiments of the invention described herein are capable of operation in other orientations than described or illustrated herein.

The terms “generating means” and “generator” may be used interchangeably. Also the terms “controlling means” and “controller” may be used interchangeably, and the same applies to the terms “sensor” and “sensor element”.

“As function of time” as used herein, refers to both in a continuous and discontinuous manner. In a discontinuous manner may be at predefined intervals, regularly or irregularly spaced.

Furthermore, the present invention will be described by means of magnetic or magnetizable objects being referred to as magnetic particles. The term “magnetic particle” is, unless otherwise specified, to be interpreted broadly such as to include any type of magnetic particles, e.g. ferromagnetic, paramagnetic, superparamagnetic, etc. as well as particles in any form, e.g. magnetic spheres, magnetic rods, a string of magnetic particles, or a composite particle, e.g. a particle containing magnetic as well as optically-active material, or magnetic material inside a non-magnetic matrix. Optionally, the magnetic or magnetizable objects may be ferromagnetic particles which contain small ferromagnetic grains with a fast magnetic relaxation time and which have a low risk of clustering. Again, the wording used is only for the ease of explanation and does not limit the invention in any way. The magnetic particles may comprise further properties such as optical colors. The presence of different, e.g. optical properties in the magnetic particles can be used to broaden the possibilities in the sensing methods and allows for multiplexing of the assay.

The term “sensor surface” for the purpose of the present invention, interchangeably also referred to as “surface of the sensor device”, relates to any surface of the recipient, i.e. reaction chamber, wherein the sample fluid is contained, which is in contact with said sample fluid and which is located in the spatial area in the vicinity of the sensor element, wherein said sensor element operates.

The term “reaction chamber” as used herein refers to any item that may serve as a container to hold the sample fluid, i.e. the assay. Said container is optionally detachable from the sensor device of the present invention, i.e. the reaction chamber may be integrated part of the device or instrument as well as an independent object that can be placed on, in or near the sensor device and be removed again.

In a first aspect, the present invention provides a sensor device suitable for detecting a magnetic particle in the sample fluid. Such a method may be especially suitable for detecting biological, chemical or biochemical analytes in a sample, whereby the magnetic particle may be specifically attached to a target in the sample or specifically detached from a target in the sample as e.g. in an 1-x assay. The sensor device may be adapted to detect magnetic particles in a fluid, a liquid, a gas, a visco-elastic medium, a gel or a tissue sample, in general all referred to as “sample fluid”.

By way of illustration, the present invention not being limited thereto, an exemplary sensor device according to the first aspect is shown in FIG. 1, indicating standard and optional components. The sensor device 100 is adapted for detecting at least one magnetic particle 102 in a sample 104. The sensor device 100 advantageously may comprise a reaction chamber 106 for holding the sample during the assay. The reaction chamber 106 can be a disposable item to be used with a compact reader, containing the one or more magnetic field generating means and one or more detection means. The reaction chamber may be e.g. a well plate or cuvette, fitting into an automated instrument. The reaction chamber 106 may be adapted to hold small sample volumes. For the purpose of the present invention, magnetic particles with different shapes can be used, e.g. spherical, rod-like, two-bead clusters. The magnetic particles can have small dimensions. In particular, for the purpose of the present invention, the magnetic particles have at least one dimension ranging between 0.1 nm and 10000 nm, more in particular between 3 nm and 3000 nm, and even more in particular between 10 and 1000 nm. The magnetic particles can acquire a magnetic moment due to an applied magnetic field (e.g. they can be paramagnetic or superparamagnetic) or they can have a permanent magnetic moment. The particles can be a composite, e.g. consist of one or more small magnetic particles inside or attached to a non-magnetic material, or e.g. consist of two or more clustered or agglutinated small magnetic particles. As long as the particles generate a non-zero response to the frequency of a high frequency H_{AC}, i.e. when they generate a magnetic susceptibility or permeability, they can be used. The magnetic particles may display further properties, e.g. optical properties such as fluorescence. These differing properties may allow for multiplexing in the assay. Label multiplexing may occur by using distinguishable properties for different particles within the same sensor category. For example different magnetic materials yielding distinguishable signals. Alternatively, different properties selected from different sensor categories can be used, e.g. using a combination of magnetic and optical labels which will each be selectively measured by respectively a magnetic sensor element and optical sensor element. The device and method can be used with several biochemical assay types, e.g. binding/unbinding assay, sandwich assay, competition assay, displacement assay, enzymatic assay, agglutination assay, amplification assay, etc. The device and method can be used with different classes of molecules and biological entities, e.g. DNA, RNA, proteins, small molecules. In addition to molecular assays, also larger moieties can be detected or probed, e.g. cells, viruses, or fractions of cells or viruses, tissue or tissue extract, etc. Molecular targets often determine the concentration and/or presence of larger moieties, e.g. cells, viruses, or fractions of cells or viruses, tissue extract, etc.

The sensor device 100 furthermore is adapted for comprises at least one rotating magnetic field generating means 108 for applying a rotating magnetic field to the sample fluid 104 containing at least one magnetic particle 102. The at least one rotating magnetic field generating means 108 may for example be a alternating current magnetic field generating means, although the invention is not limited thereto. Such a rotating magnetic field may be generated in any suitable way such as using wires, coils, magnetic materials, electromagnets or the like. It may be generated on-chip or off-chip. On-chip means that the generator is integrated in the device, whereas off-chip refers to the generator being external to or independent from the device. The sensor device 100 according to embodiments of the present invention also comprises a controller 110 for operating the rotating magnetic field generating means 108 at a frequency substantially higher than the critical slipping frequency of the magnetic particle present in the sample fluid. It is known that magnetic particles rotate in such a rotating magnetic field for frequencies of the applied field up to a maximum at a certain frequency, the so-called critical slipping frequency. Above the critical slipping frequency the physical rotation of the magnetic particle tends not to follow the rotations of the applied magnetic field. According to embodiments of the present invention, surprisingly at frequencies substantially higher than the critical slipping frequency, the physical rotation of the magnetic particle increases again. In other words, it has surprisingly been found that frequencies substantially higher than the critical slipping frequency also can be used for determining magnetic particles or parameters thereof in a sample. The frequency of the applied rotating magnetic field may for example be a factor 10 higher than the critical slipping frequency. The H_{AC} frequency may be at least 10 times higher than the critical slipping frequency, or at least 100 times higher, or at least 1000 times higher. The critical slipping frequency is typically a few Hz whereas the rotation caused by Neel relaxation, i.e. rotation at substantially higher frequency of the rotating magnetic field, starts to dominate above a few kHz increasing up to a few MHz. Typically, the applied H_{AC} frequency is at least about 5 Hz, or in particular at least about 10 Hz or 20 Hz. And typically, the applied H_{AC} frequency is at most about 10 MHz, more in particular at most about 1 MHz. The applied rotating magnetic field may operate at a frequency that induces a rotational frequency of the targeted magnetic particle(s) of at least 50% compared to the rotational frequency of the magnetic particle(s) at the critical slipping frequency applying a rotating magnetic field with the same amplitude. The induced rotation frequency of the magnetic particle(s) may be at least at 60% compared to the rotational frequency of the magnetic particle(s) at the critical slipping frequency applying a rotating magnetic field with the same amplitude, more in particular at least 70%. The actual frequency desired depends on the size/type of magnetic particles used. To obtain maximum signal it is advantageous to use a frequency that is close to the second maximum (as illustrated in FIG. 4, double arrow) regarding the measured effect of the applied AC magnetic field. For the beads used in the experiments illustrated by FIG. 4, the desired frequency is around 600 kHz. Depending on the assay and the type of particles used, this might be considerably lower/higher due to the strong dependence of Neel relaxation time on e.g. grain size of the magnetic particles used. The critical slipping frequency can be measured optically or magnetically, by studying particle rotation as a function of the applied field rotation frequency. Within the framework of the present invention, there are two possibilities for determining the critical slipping frequency. A first option is characterizing a batch of beads prior to the agglutination assay so the critical slipping frequency is known before beads are used in the actual device in which the assay is performed, or before the beads are used in a method according to the invention. Alternatively, the critical slipping frequency is determined in the device in which also the agglutination assay is performed. The critical slipping frequency can be determined by optical microscopy on a rotating bead while sweeping the field frequency from 0 Hz up to a frequency well above the critical slipping frequency. The critical slipping frequency can also be determined by using a magnetic field sensor that measures the dipole field of the rotating bead while sweeping the frequency of the applied field. Lock-in detection of the output signal detects gives the sensor output at the applied field frequency. Once the permanent magnetic moment of the bead can not follow the applied field (critical slipping frequency) the signal at the actuation frequency shows a drop.

The applied field might be different for different particles. Regarding amplitude of the applied rotating field as well as the frequency of the applied field, because the field frequency has to be lower than the fastest Neel relaxation in order to rotate the bead. The Neel relaxation depends strongly on the grain size of the bead and varies between different kinds of beads. Rotation of superparamagnetic particles works for relatively low field amplitudes (due to high susceptibility) i.e. >=0.1 mT. In contrast, for paramagnetic particles much higher fields are required.

Several advantages result from operating the rotating magnetic field at much higher frequencies than the critical slipping frequency. High-frequency excitation reduces or minimizes the dipole-dipole interactions between magnetic particles, which improves the sensor reproducibility. The signal-to-noise ratio and the detection sensitivity are high due to the use of a modulation technique. Embodiments of the present invention take advantage of this unexpected finding. The latter will be illustrated in detail by way of a number of examples below. As mentioned above, a rotating magnetic field may induce a torque on a magnetic particle. The size of the torque on the magnetic particle under influence of H_{AC} is given by the magnitude of the vector cross product

\vec{m}×\vec{B}=m·B·sin(α)

with m the magnetic moment, B the applied field, and α the angle between the two vectors. In other words, the torque can be determined by measuring the phase lag between the particle magnetization and the applied magnetic field. The phase lag can for example be determined in an optical measurement (e.g. detecting the magneto-optical Kerr rotation or magnetic circular dichroism) and/or a magnetic measurement (e.g. using a magneto-resistive sensor). Alternatively, the rotational excitation caused by H_{AC} can be used to optimise the exposure of particles to e.g. the sensor surface or to optimise the molecular association and dissociation conditions.

The particles used may advantageously be paramagnetic or superparamagnetic particles. This has the advantage that the torque (resulting from application of the rotating magnetic field) can be applied to the particles independent of the orientation and the mobility of the particles. For example, even to particles that are static due to biological binding, a well-defined torque can be applied, irrespective of the particle orientation.

The rotational excitation caused by the rotating magnetic field also can be used to optimise the exposure of particles to e.g. the sensor surface or to optimise the molecular association and dissociation conditions.

The sensor device 100 furthermore comprises at least one sensor element 112 for sensing an effect of the rotating magnetic field on the magnetic particle. Such an effect may be any or a combination of a magnetic effect, an optical effect from the magnetic particle or a luminescent particle coupled thereto, an acoustic effect, an electric effect etc. For the purpose of the present invention, the at least one sensor element thus may be selected from the group consisting of a magnetic sensor element, an optical sensor element, an acoustic sensor element and an electrical sensor element. The sensor element 112 may be an optical sensor operating on the basis of several optical detection concepts such as evanescence, fluorescence, phosphorescence, scattering, etc. The sensor element 112 may be a magnetic sensor element such as for example a magnetoresistive sensor selected from the group consisting of an AMR, a GMR and a TMR sensor element or a Hall sensor element. Advantages of using a magnetic sensor element are that detection can be done in raw samples, whereby less or no interference of raw sample components may be present, and, no fluid wash steps necessary, which besides speed and ease, may increase sensitivity of the assay and allow for the detection of low-affinity interactions. The same advantage applies to other methods, when very large signals are generated from the detection labels. The at least one sensor element 112 is adapted for detecting and/or an effect of the rotating magnetic field on the magnetic particle (102). The sensor element may for example be adapted for detecting or measuring a parameter related to a rotational or motional behaviour of the magnetic particle (102). In another particular embodiment, the at least one sensor element is a magnetic sensor element. The sensor element 112 thus may register the characteristics of the movement of the magnetic particle under influence of H_{AC}. Examples of such characteristics of the movement are speed, regularity of the movement e.g. creeping of the rotation, and the like. In particular, magnetic and optical sensors may be used in combination in the device or method of the invention. The sensor element 112 may be positioned on a substrate 114, whereon also a magnetic field generator may be integrated. The substrate may comprise semiconductor material, glass, plastic, ceramic, silicon-on-glass, silicon-on sapphire substrates. The sensor element 112 may be coupled to read-out and control circuitry 116 which may or may not be part of the sensing device. The read-out and control circuitry 116 may be adapted for reading out the sensor element 112 for outputting the sensed effects. The sensor device 100 furthermore may comprise a processor 118, e.g. coupled to the read-out and control circuitry 116, whereby the processor is adapted for deriving from the sensor read-out, i.e. from the sensed effect, a property of the sample fluid under characterisation. The property may be the viscosity of the sample fluid. More particularly, depending on the performed assay, the processor 118 may be adapted for deriving a presence and or amount of target, and thus an amount of corresponding analytes present in the sample fluid. Such processing may be performed in an automatic or automated way. It may be based on a neural network, use particular algorithms, be based on predetermined criteria, use look-up tables, etc. The results may be based on a particular binding ratio of the magnetic particles to the targets. Such a binding may be directly or indirectly. The sensed magnetic particles may be unattached to a wall of the reaction chamber, e.g. unattached to a sensing surface. Alternatively or in addition thereto, the sensor device 100 may have at least one functionalised sensor surface and the processor may be adapted for deriving a type or degree of binding of the magnetic particle from the measured effect.

The sensor device furthermore may comprise an additional magnetic field generating means 120 for applying a translational force to the magnetic particles. The additional magnetic field generating means may in particular be an external field generating means. Such an additional magnetic field generating means 120 may generate a non-uniform magnetic field. It may be adapted for inducing a washing step. Alternatively or in addition thereto it may be adapted for inducing a concentration and/or separation step. Alternatively or in addition thereto, it may be adapted for inducing a mixing step.

In a further embodiment, the sensor device further comprises modulating means for modulating the torque induced by the rotating magnetic field. The thereby induced modulated rotation can be used to distinguish between biological binding and non-specific binding via wide-area interactions (e.g. vdWaals, electrostatic). For example, upon rotational excitation particles bound via a single molecular bond will show a movement that reflects the presence of a tether between the particle and the surface, while particles bound via wide-area interactions will show a movement with a creeping character. The modulating means 122 is also shown in FIG. 1.

It is an advantage of embodiments according to the present invention that the sensor device may be adapted for distinguishing a direct or indirect specific binding from a less specific binding between the at least one magnetic particle and a surface of another entity.

In a particular embodiment according to the first aspect, the device and method of the invention are used to perform an assay whereby the magnetic particle to be measured is attached to the sensor surface. In particular, the number of magnetic particles present in a sample fluid can be determined using the method or device of the present invention, without need for attachment to the sensor surface.

In another particular embodiment according to the first aspect, the device and method of the invention are used to perform an assay whereby the magnetic particle to be measured is unattached to the sensor surface. Non-binding to the sensor surface is in particular advantageous because there is no need for complicated surface structuring (such as surface patterning and surface modification). This can result in significantly simplified manufacturing of magnetic sensing devices.

The method and device according to the present invention allow for the detection and/or characterization of interactions, even low-affinity interactions, e.g. in the determination of a particular target in a sample. A first type of information that may be obtained is the presence of such low-affinity target in the sample. A second type of information that may be obtained is, in line with the density of magnetic particles being determined at the sensor surface, the concentration of the target in the sample. And a third type of information that may be obtained concerns the nature or type of the attachment to the sensor surface. Due to the excitation at high frequencies, the applied torque can be more easily controlled and modulated, thereby allowing distinguishing between different types of attachment. Modulated rotation can be used to distinguish between biological binding and non-specific binding via wide-area interactions (e.g. Van der Waals forces, electrostatic force). For example, upon rotational excitation particles bound via a single molecular bond will show a movement that reflects the presence of a tether between the particle and the surface, while particles bound via wide-area interactions will show a movement with a creeping character. The rotational force or torque is also well-defined due to its independence of particle orientation. Therefore the method and device can be used to perform a bond-force measurement and/or for applying a stringency force (e.g. rotational magnetic washing) both for magnetic particles attached to and unattached to the sensor surface.

In a second aspect, the present invention relates to a method for characterizing a fluid sample. The method therefore uses at least one magnetic particle in a fluid sample that is adapted for binding to at least one target of interest. The target thereby may be an analyte of interest or an object corresponding therewith. The method comprises obtaining a fluid sample comprising at least one magnetic particle adapted for binding to at least one target. The obtaining may be in any suitable way whereby a sample fluid with at least one magnetic particle is obtained in a reaction chamber. The magnetic particle(s) may be mixed with the sample fluid prior to entering the reaction chamber or they may be brought in contact with each other by bringing the sample fluid in the reaction chamber or thereafter. The method furthermore comprises applying a rotating magnetic field at a frequency substantially higher than the critical slipping frequency of the magnetic particle present in the sample fluid. The rotating magnetic field and corresponding frequency may be subject to the same features and advantages as set out for the first aspect. The method furthermore comprises measuring an effect of the rotating magnetic field on the at least one magnetic particle in said fluid sample. Such measuring may be performed in any suitable way, such as for example using a magnetic sensing technique, an optical sensing technique, an electrical sensing technique, an acoustic sensing technique, etc.

The method also comprises deriving from the measured effects a presence and/or amount of the target, and thus corresponding analytes, in the fluid sample. The obtained data can be derived as an end-point measurement, as well as by recording signals kinetically or intermittently. In a particular embodiment, the method of the invention further comprises the step of further processing the measured data. Processing of the data, such as e.g. the deriving step, may be performed in an automatic and/or automated way. It may be performed according to a predetermine algorithm, using look-up tables (LUT), according to predetermined criteria, etc. It may be computerised.

In a third aspect, the present invention also relates to a for use in a sensor device as described in the first aspect. The controller may be adapted for operating the at least one rotating magnetic field generating means so as to apply a rotating magnetic field to a magnetic particle in a sample fluid at a frequency substantially higher than the critical slipping frequency of a magnetic particle. The latter may be by providing appropriate drive and control signals. Such a controller may be made in hardware and/or software.

By way of illustration, the present invention not being limited thereto, a number of examples are described in more detail as well as a number of standard or optional steps of the method, the present invention not being limited thereto.

A first set of particular examples illustrates the physical rotation of magnetic particles when a rotational frequency substantially higher than the critical slipping frequency is used for the rotating magnetic field. FIG. 2A to 4 illustrate, by way of example the present invention not being limited thereto, the phenomenon whereby rotation of the particles is obtained up to a given frequency, referred to as the slipping frequency and at frequencies substantially higher than the slipping frequency. FIG. 2a shows the rotation frequency of a single magnetic particle as a function of the applied angular frequency of the rotating magnetic field. The arrow indicates the critical slipping frequency. The data shown in the example of FIGS. 2a, 2b, 3a and 3b were obtained for a magnetic particle with a diameter of 2.8 micrometer, having a large non-permanent magnetizability and a small permanent magnetization. In the example of FIG. 2a, the bottom current (I_{bottom}) for generating the rotating magnetic field was 0.046 Ampere (A). FIG. 2B shows the critical slipping frequency as a function of current applied to the current wires generating the rotating magnetic field. A current of 100 mA corresponds to a field of 2 mT at the position of the magnetic particle in the present example. The linear behavior indicates that the magnetic torque originates form a permanent magnetization in the magnetic particle. FIG. 3a shows the optically measured rotation frequency of the single magnetic particle as a function of applied angular frequency of a rotating magnetic field, in a wide frequency range expressed in a logarithmic scale in the X-axis. The effect of the permanent magnetisation is visible in the low frequency range (lower than about 10 Hz), and the effect of the non-permanent magnetization is visible in the higher frequency range (up to about 10 MHz). FIG. 3b shows the magnetic particle rotation frequency as a function of current applied to the current wires at a frequency of 40 kHz. The quadratic behavior (indicated in FIG. 3b) of the magnetic particles in the rotating magnetic field indicates that the magnetic torque originates from the susceptibility of the magnetic particle, i.e. a non-permanent magnetization. FIG. 4 indicates the frequency spectrum of a rotating two-bead cluster composed of two particles with a diameter of 1 micrometer as function of the applied angular field frequency. The double arrow in FIG. 4 indicates that rotation frequency of the magnetic particle under the influence of such AC magnetic field operated at a much higher frequency that the critical slipping frequency, rises to a maximum. The maximum can be higher than the rotation frequency at the critical slipping frequency. Note that both levels depend on the magnitude of the applied field in a different way: at low frequencies the rotation frequency increases linearly with the applied field (as in FIG. 2b), while at high frequencies the rotation frequency increases quadratically with the applied field strength (as in FIG. 3b). These figures all illustrate the unexpected finding wherein at frequencies higher than the critical slipping frequency, the rotation frequency of the particle increases, respectively for a single magnetic particle and a cluster of two magnetic particles. As indicated above, several advantages may result from operating the H_{AC} at much higher frequencies than the critical slipping frequency. For example, high-frequency excitation may minimise the dipole-dipole interactions between magnetic particles, thereby improving the sensor reproducibility. Another advantage can be clearly derived from FIGS. 2 A and 3. Unlike the steep increase and steep decline of the rotation frequency of the magnetic particle at lower H_{AC} frequencies, i.e. in the slipping frequency range, the rotational behaviour of the magnetic particle under influence of an AC magnetic field at much higher frequency is not as much dependent on the actual frequency of the AC magnetic field. As a result, the measurement of the physical rotation of magnetic particles under influence of such AC magnetic field at much higher frequencies is much more stable, much more reliable and generally applicable, in particular for frequencies below the second maximum of the graph (e.g. at about 800 kHz in FIG. 4).

In a second particular set of examples, measurement of effects with different detection techniques is illustrated, the present invention not being limited thereto. In one example, radiative labels, such as e.g. luminescent or fluorescent labels, are embedded in or attached to the magnetic particles that are used. For example, antigens may be coupled to fluorescent magnetic particles or to both fluorescent and non-fluorescent magnetic particles. Excitation of the fluorescent magnetic particles can be done using an irradiation source, such as for example via focused laser beam or via evanescent field excitation allowing optical detection of such labels. Detection can be done in any suitable way, such as for example using evanescent fields, scattering, imaging, or confocal detection using a high-NA lens. The use of fluorescent magnetic particles enables multiplexing by using different fluorophores, which differ in excitation and/or emission wavelengths. As another example of an embodiment, detection can be done optically, using fluorescent labels (initially either free, or embedded in or attached a non-magnetic particle) in combination with magnetic particle labels. The measurement of agglutination in this example then may not be based on cluster formation of magnetic particles but on the increase in fluorescence of magnetic particles. For example, antigens, labelled with either a fluorescent or magnetic particle label, are mixed, and exposure to a sample containing antigen-specific antibodies will lead to binding of fluorescent labels to magnetic particle labels. For this embodiment, magnetic particles can be actuated to a non-binding sensor surface and surface specific detection of fluorescence labels can be done. Surface specific excitation of the fluorophores can be done using a radiation source, e.g. using a focused laser beam or via evanescent field. Detection can be done either via confocal detection (surface sensitive detection) or using a high-NA light-collection lens (not surface sensitive). By using this method the background fluorescence from excess labels and from the sample fluid itself can be reduced or even minimized. Multiplexing of the assay based on differential labelling of the particles can be easily envisioned making use of different fluorescent labels. Optical detection can be done also by Surface-Enhanced Resonance Raman spectroscopy (SERRS). SERRS is an ultra-sensitive method for detection of molecules or species by adsorption of the molecule or species that is optically labeled on colloidal particles, e.g. silver particles. The optical label is a suitable dye molecule (such as Rhodamine) causing plasmon and dye resonance when the colloidal particles cluster in a controlled way. It is known that magnetic particles exist with a metallic coating. If for example antigens (to which the target, i.e. antibodies, binds) are coupled to such silver-coated magnetic particle, while the antigens are also coupled to a suitable dye, antigen-specific antibodies will lead to linking of the dye to the silver-coated magnetic particles. Magnetic actuation will lead to cluster/pillar formation which will lead to dye resonance. SERRS can be detected after actuation to a non-binding sensor surface in an evanescent field. In such a set-up, antibody detection can be done in a single chamber omitting fluid wash steps since the detection is surface specific and not disturbed by unbound dyes from solution.

In another particular example, an optional concentration and/or separation step as can be induced using the optional additional magnetic field generating means 120 is discussed in more detail. An inhomogeneous magnetic field may be applied that exerts a force on magnetic particles in a defined direction, i.e. following the gradient of the field. Actuation of the magnetic particle under influence of the applied translational magnetic force may differ according to size and shape of the magnetic particles. In a particular embodiment, the unidirectional magnetic field is oriented substantially parallel to the surface of the sensor device. It is an advantage of the present invention that using such parallel unidirectional field lead to a separation of different types of magnetic particles, which then can be measured separately. Alternatively the actuation of the magnetic particles may increase the chance to collide with other particles, analytes in the sample or ligands on the sensor surface, thereby increasing the chance to interact. Alternatively, the unidirectional magnetic field may be oriented substantially perpendicular to the surface of the sensor device. Such perpendicular orientation may direct magnetic particles towards the sensor surface, or away from the sensor surface. Again, such actuation of the magnetic particles allows speeding up assays by enhancing the interactions in the sample fluid or with the sensor surface.

In another independent or dependent embodiment of the present invention a measurement method and an apparatus for the measurement of the viscosity of a sample fluid in a magnetic biosensor using a rotational magnetic field is disclosed. Preferably, in accordance with embodiments of the present invention, the rate of change of a sensor signal should only be a function of a concentration of target molecules. Therefore the influence of the viscosity of the fluid sample on the sensor reading needs to be minimised. As indicated above magnetic particles with different shapes can be used, e.g. spherical, rod-like, two-bead clusters but for this embodiment they are preferably all identical in one sample. The magnetic particles can have small dimensions. In particular, for the purpose of the present invention, the magnetic particles have at least one dimension ranging between 0.1 nm and 10000 nm, more in particular between 3 nm and 3000 nm, and even more in particular between 10 and 1000 nm. The magnetic particles can acquire a magnetic moment due to an applied magnetic field (e.g. they can be paramagnetic or superparamagnetic) or they can have a permanent magnetic moment. The particles can be a composite, e.g. consist of one or more small magnetic particles inside or attached to a non-magnetic material, or e.g. consist of two or more clustered or agglutinated small magnetic particles. As long as the particles generate a non-zero response to the frequency of a high frequency H_{AC}, i.e. when they generate a magnetic susceptibility or permeability, they can be used.

FIG. 5 is a schematic representation of a rotationally driven magnetic particle, where the phase lag is given by ωt− [symbol] . The external field is represented by B and the magnetization of the magnetic microsphere is m. Determination of the critical slipping frequency can be used in the measurement of viscosity. In a viscous fluid, measurement of the critical slipping frequency ω_{c} allows for the measurement of properties like the dynamic viscosity which can be derived from an equation:

$$η = \frac{m \cdot B}{k \cdot V \cdot {ω}_{c}}$$

If all of the microparticles have the same shape, volume, and magnetic content, a spatial distribution of viscosity can be measured by observing the particles individually and determining their cristical slipping frequency. Such measurements can be applied to complex fluids where pores of various sizes and spacings are present. Each particle becomes a local viscometer. By using the spatially resolved local viscometers, i.e. by determining the critical slipping frequency of different particles at different positions, the effective viscosity at each of these various positions in the complex fluid can be measured. Thus, this technique can be used as a colloidal probe in microrheology. Due to the variation in the properties of the particles it is preferred to use a single particle that is moved to various parts of the sample volume to measure the local viscosity. Using a single probe it is possible to perform accurate viscosity experiments. By combining this technique with optical tweezers, it is possible to manipulate a magnetic particle, e.g. after viscosity calibration, in systems like biological environments or near fluid-solid or fluid air interfaces.

As indicated above the critical slipping frequency can be determined by any of a variety of methods. For example, optical microscopy can be performed on a rotating bead while sweeping the field frequency from 0 Hz up to a frequency well above the critical slipping frequency. This embodiment of the present invention is shown schematically in FIG. 6. Items with the same reference numbers as in FIG. 1 refer to exactly the same items and the relevant description of these items above is incorporated here. FIG. 6 has device 125 for the optical capturing of an image of one or more particles rotating in the rotating magnetic field generated by rotating magnetic field generating means 108. The optical capturing device 125 can include a microscope or a microscope with a camera, etc. The camera can be a CCD (such as a Rope Coolsnap ES CCD camera) or CMOS camera or any other digital camera with an image output interface. The camera can detect reflected light from the partiscles or may use transmitted light through the sensor. A light source such as a Xenon lamp (not shown) may be used to illuminate the particles. The controller 110 in this embodiment is adapted to ramp the frequency of the rotational field from below to above the critical slipping frequency to allow observation and optionally detection of the critical slipping frequency. Optionally the optical capturing device 125 can transmit an output of an image (e.g. from a CCD or CMOS camera interface) to image processing means 126 that is adapted to detect when the critical slipping frequency has been reached or exceeded. This can be achieved when the image processing device is a computing device running image analysis software. Such software may include for example Metamorph software as supplied by Universal Imaging Corp. USA. If the particles are fluorescent, the fluorescing radiation may be used to determine the rotation of the particles. Generally the signal from the camera is analysed at the pixel level so as to obtain values for an individual particle. Due to the rotation, the intensity of light received in the camera will vary in time with the rotation speed of the particle or a multiple of that speed. A value relating to the rotational frequency of the particle can be obtained by application of a Fast Fourier transform to the output of the camera.

The critical slipping frequency can also be determined by using a magnetic field sensor that measures the dipole field of the rotating particle while sweeping the frequency of the applied field. For example the sensor element one sensor element 112 of FIG. 1 may be adapted to perform this function. Lock-in detection of the output signal detects gives the sensor output at the applied field frequency. Once the permanent magnetic moment of the bead can not follow the applied field (critical slipping frequency) the signal at the actuation frequency shows a drop.

It is an advantage of embodiments according to the present invention that devices, methods and systems are obtained that are suitable for sensor multiplexing (i.e. the parallel use of different sensors and sensor surfaces), label multiplexing (i.e. the parallel use of different types of labels) and chamber multiplexing (i.e. the parallel use of different reaction chambers).

It is an advantage of embodiments according to the present invention that devices are obtained that can be used in automated high-throughput testing. Such systems may be systems with microtiterplates or vials, and flow systems (as in flow cytometry).

It is an advantage of embodiments according to the present invention that devices can be obtained allowing rapid, robust, and easy to use point-of-care biosensors.

The above-described method embodiments of the present invention may be implemented in a processing system 200 such as shown in FIG. 7. FIG. 7 shows one configuration of processing system 200 that includes at least one programmable processor 203 coupled to a memory subsystem 205 that includes at least one form of memory, e.g., RAM, ROM, and so forth. It is to be noted that the processor 203 or processors may be a general purpose, or a special purpose processor, and may be for inclusion in a device, e.g., a chip that has other components that perform other functions. Thus, one or more aspects of the present invention can be implemented in digital electronic circuitry, or in computer hardware, firmware, software, or in combinations of them. The processing system may include a storage subsystem 207 that has at least one disk drive and/or CD-ROM drive and/or DVD drive. In some implementations, a display system, a keyboard, and a pointing device may be included as part of a user interface subsystem 209 to provide for a user to manually input information. Ports for inputting and outputting data also may be included. More elements such as network connections, interfaces to various devices, and so forth, may be included, but are not illustrated in FIG. 7. The various elements of the processing system 200 may be coupled in various ways, including via a bus subsystem 213 shown in FIG. 7 for simplicity as a single bus, but will be understood to those in the art to include a system of at least one bus. The memory of the memory subsystem 205 may at some time hold part or all (in either case shown as 201) of a set of instructions that when executed on the processing system 200 implement the steps of the method embodiments described herein. Thus, while a processing system 200 such as shown in FIG. 7 is prior art, a system that includes the instructions to implement aspects of the methods for characterising a sample fluid is not prior art, and therefore FIG. 7 is not labelled as prior art.

The present invention also includes a computer program product, which provides the functionality of any of the methods according to the present invention when executed on a computing device. Such computer program product can be tangibly embodied in a carrier medium carrying machine-readable code for execution by a programmable processor. The present invention thus relates to a carrier medium carrying a computer program product that, when executed on computing means, provides instructions for executing any of the methods as described above. The term “carrier medium” refers to any medium that participates in providing instructions to a processor for execution. Such a medium may take many forms, including but not limited to, non-volatile media, and transmission media. Non volatile media includes, for example, optical or magnetic disks, such as a storage device which is part of mass storage. Common forms of computer readable media include, a CD-ROM, a DVD, a flexible disk or floppy disk, a tape, a memory chip or cartridge or any other medium from which a computer can read. Various forms of computer readable media may be involved in carrying one or more sequences of one or more instructions to a processor for execution. The computer program product can also be transmitted via a carrier wave in a network, such as a LAN, a WAN or the Internet. Transmission media can take the form of acoustic or light waves, such as those generated during radio wave and infrared data communications. Transmission media include coaxial cables, copper wire and fibre optics, including the wires that comprise a bus within a computer.

It is to be understood that although preferred embodiments, specific constructions and configurations, as well as materials, have been discussed herein for devices according to the present invention, various changes or modifications in form and detail may be made without departing from the scope and spirit of this invention.

1. A sensor device (100) for detection of at least one magnetic particle (102) in a sample fluid (104), the sensor device (100) comprising:
at least one rotating magnetic field generating means (108) for applying a rotating magnetic field to the sample fluid (104) containing at least one magnetic particle (102),
a controller (110) for operating the at least one rotating magnetic field generating means (108) so as to apply a rotating magnetic field at a frequency substantially higher than the critical slipping frequency of the magnetic particle, and
a sensor element (112) for detecting and/or measuring an effect of the rotating magnetic field on the at least one magnetic particle (102).

2. A sensor device (100) according to claim 1, wherein the controller (110) is adapted for operating the at least one rotating magnetic field generating means (108) so as to apply a rotating magnetic field with a frequency at least a factor 10 higher than the critical slipping frequency of the magnetic particle.

3. A sensor device (100) according to claim 1, wherein the sensor element (112) is adapted for detecting and/or measuring a parameter related to rotational or motional behaviour of the at least one magnetic particle under influence of said rotating magnetic field.

4. A sensor device (100) according to claim 3, wherein the sensor element (112) is adapted for distinguishing a specific binding from a less specific binding between the at least one magnetic particle (102) and a surface of another entity.

5. A sensor device (100) according to claim 1, wherein the rotating magnetic field generating means (108) comprises an alternating current magnetic field generating means.

6. A sensor device (100) according to claim 1, wherein the magnetic field generating means (108) comprises a two-dimensional wire structure.

7. A sensor device (100) according to claim 1, wherein the sensor device furthermore comprises an additional magnetic field generating means (120) for applying a translational force to the magnetic particles.

8. A sensor device according to claim 7, wherein the sensor device comprises a reaction chamber (106) with walls for holding the sample fluid (104) during said detecting and/or measuring, wherein the magnetic particle is directly or indirectly bound to a wall of the reaction chamber and wherein the processor (118) is adapted for deriving from said measured effect a property of bound of the magnetic particle.

9. A sensor device according to claim 1, wherein the sensor device comprises a reaction chamber (106) for holding the sample fluid (104) during said detecting and/or measuring, the reaction chamber (106) having walls whereby the walls are not and/or non-specifically functionalised with respect to a target in the sample.

10. A method for characterising a fluid sample, the method comprising:
obtaining a fluid sample comprising at least one magnetic particle adapted for binding to at least one target,
applying a rotating magnetic field at a frequency substantially higher than the critical slipping frequency of the magnetic particle,
measuring an effect of the rotational magnetic field on the at least one magnetic particle in said fluid sample, and
deriving therefrom a presence and/or amount of said at least one target in the fluid sample.

11. A method according to claim 10, wherein applying a rotating magnetic field comprises applying a rotating magnetic field with a frequency at least a factor 10 higher than the critical slipping frequency of the magnetic particle.

12. A method according to claim 10, wherein measuring the effect on the at least one magnetic particle comprises measuring the effect on the magnetic particle directly or indirectly bound to a sensor surface, and wherein said method furthermore comprises deriving an property of the bound property of the magnetic particle to the sensor surface from a motional freedom of the bound magnetic particle.

13. A controller for use in a sensor device (100) according to claim 1, the controller (110) being adapted for operating at least one rotating magnetic field generating means (108) so as to apply a rotating magnetic field to a magnetic particle in a sample fluid at a frequency substantially higher than the critical slipping frequency of a magnetic particle.

14. A computer program product adapted for, when executed on a computer, performing the method of characterizing a fluid sample according to claim 10.

15. Transmission of the result of characterizing the fluid sample by the computer program product of claim 14 over a local or wide area telecommunications network.
